(19) United States
(12) Patent Application Publication
(10) Pub. No.: US 2009/0250337 A1
(43) Pub. Date: Oct. 8, 2009

(54) TUBULAR TARGET HAVING A CONNECTING LAYER ARRANGED BETWEEN THE TARGET TUBE AND THE CARRIER TUBE

(75) Inventors: Christoph Simons, Biebergemünd (DE); Martin Schlott, Offenbach (DE); Markus Schultheis, Flieden (DE); Martin Weigert, Hanau (DE); Lars Gusseck, Nidderau (DE)

Correspondence Address: PANITCH SCHWARZE BELISARIO & NADEL LLP, ONE COMMERCE SQUARE, 2005 MARKET STREET, SUITE 2200, PHILADELPHIA, PA, 19103, US

(73) Assignee: W.C. HERAEUS GMBH, Hanau (DE)

(21) Appl. No.: 11/721,677

(22) PCT Filed: Dec. 7, 2005
(86) PCT No.: PCT/EP2005/013084

§ 371 Date: Nov. 27, 2007

(30) Foreign Application Priority Data
Dec. 14, 2004 (DE) 10 2004 060 423.1

(51) Int. Cl. C23C 14/34

(52) U.S. Cl. 204/192.15; 204/298.13

(57) ABSTRACT

A tubular target is provided having a cylindrical carrier tube, at least one target tube arranged on its exterior surface, and a connecting layer arranged between the target tube and the carrier tube. The connecting layer is electrically conductive and has a wetting degree of >90%.

### CROSS-REFERENCE TO RELATED APPLICATIONS

This application is a Section 371 of International Application No. PCT/EP2005/013084, filed Dec. 7, 2005, which was published in the German language on Jun. 22, 2006, under International Publication No. WO 2006/063721 A1 and the disclosure of which is incorporated herein by reference.

### BACKGROUND OF THE INVENTION

The invention relates to a tubular target with a cylindrical carrier tube and at least one target tube arranged at its outer surface, wherein a connecting layer is arranged between the target tube and the carrier tube.

In order to sputter large-area substrates, as for example, glass for the construction/architectural field, for automobile glass, and for flat image screen panels, large-area flat or planar targets are used. These targets are characterized in a relatively low material yield of approximately 30-40% in the sputtering process. In contrast, the use of tubular targets allows a material yield at the target up to 90% and minimizes the development of so-called redeposit zones, which tend to release particles during the sputtering process. In order to produce tubular targets, previously it was common to use thermal gun spraying, as for example, plasma spraying and arc spraying methods, in which the respective target material is directly coated onto a carrier tube by the method of the thermal spray technology. The disadvantages of this method are in general high oxygen levels, high material loss during the finishing process, and long processing periods with high energy and gas consumption.

Newer methods allow the direct molding of target material onto a carrier tube (See, for example, German Patents DE 100 43 748, DE 100 63 383). This technology is used successfully, in particular, for low-melting materials, such as Sn and Zn, and provides for target materials with a melt characteristic structural construction. Up until now, tubular sputtering materials with high melting points and wide differences in the thermal expansion coefficient relative to the carrier tube could not be produced in this manner. Therefore, some of these materials, such as Ag, Zn, SiAl, are prefabricated in short, tubular segments by melting and casting technology and subsequently pushed together and mounted on a carrier tube (Se, for example, German Patent DE 102 53 319). Here, the carrier tube provides the mechanical stability for the target construction.

The fastening of the segments on the carrier tube occurs by carrying over the production of flat targets, primarily via soldering. However, here it has been shown that the quality of this fastening is insufficient. There are multiple, partially interconnected causes for this. Some of them include: poor wetting behavior of a standard solder relative to different target materials, different wetting behavior of the solder relative to the target material and the carrier tube, very different thermal expansion coefficients between the target material and the carrier tube, the tendency to form alloys between the carrier material and the solder material, poor thermal conductivity of the target material and consequent difficulties in controlling the soldering process, difficulty in controlling the temperature over long distances during soldering, uncontrollable solder supply, and oxidation of the surfaces of the carrier material and carrier tubes as well as of the solder during the soldering process.

### BRIEF SUMMARY OF THE INVENTION

An object of the present invention is to improve the prior art and to provide a reliably operating tubular target.

The tubular target designed in segments according to the invention comprises a carrier tube and one or more target segments. It is wherein the connecting layer is electrically conducting and has a wetting degree >90%, preferably >95%.

Preferably, the degree of wetting is present both on the exterior surface of the carrier tube and on the interior surface of the target tube. It is beneficial for connector pieces, bearing receptors, or flanges to be arranged on at least one end face of the carrier tube and/or the target tube. Furthermore, it is advantageous that at least one tubular target be provided with an enlarged diameter at least at one end. The material of the target tube can be formed of Cu, Al, Zr, Mo, W, Ti, Cr, Ni, Ta, Nb, Ag, Zn, Bi, Sn, Si, or an alloy based on at least one of these elements or of a ceramic material, in the case of Al preferably from an alloy including a rare-earth element, preferably Nd.

It is further beneficial that the target tube(s) be produced from solid material blocks or produced by the direct casting of hollow cylinders, extrusion, impact extrusion, sintering, or hot isostatic pressing.

In particular, the connection layer has a conducting glue or a solder material. Either a solder material is arranged directly on the carrier tube and/or the target tube or at least a layer of an adhesive agent or a wetting agent is arranged on the carrier tube and/or the target tube and thereupon the solder material, wherein the solder material contains or is formed of In, Sn, InSn, SnBi, or other low melting solder alloys having a liquidus temperature below 300° C. The advantage of direct wetting is its cost-effectiveness relative to the version with an adhesive layer.

The carrier tube and/or the target tube may be coated with a nickel-based adhesive layer, in particular made of a nickel-aluminum or a nickel-titanium alloy. An aluminum-alloy adhesive layer also leads to a good wettability and adhesion on the basic material. The carrier tube is preferably made of steel, but other materials, such as titanium, are also possible.

In particular, the tubular target according to the invention may be used for producing display layers. It has a long life, low costs, a thermally and electrically good-conducting connection between the carrier tube and the target material for the purpose of cooling, and the formation of a stable sputtering plasma. Additional advantages are an optimal use of expensive target materials only on the exterior surface later to be removed, a directed solidification from bottom upwards by a special control of the cooling in the bonding process, leading to a connection low in pores and bubbles.

The surface of the carrier tube is pretreated in order to remove all contaminants and oxidation/scaling remnants as well as to adjust roughness. A homogenous, good heat-conducting coat <1 mm is applied onto this surface, which allows the wetting behavior for soldering and compensates thermal stress between the target material and the carrier material. Preferred coating materials are Al, Ni, Cu, Zn, and their alloys. The interior surfaces of the tube-shaped target segments are treated in a similar manner. Depending on the material properties, methods and materials coordinated thereto are to be selected. After the application of the coats both on the target side and the carrier side, another intermediate layer <1 mm is applied, coordinated to the solder to be used. Preferred materials are Al, Ni, Zn, In, Sn, Bi, and their alloys. After applying the intermediate layer both on the target side and the carrier side, a further lubricating film layer of a volatile oil is applied. This layer must be removed completely prior to the actual soldering process.

The tubular target prepared in this manner is heated homogeneously, e.g., in a heated tube furnace under an inert scavenging atmosphere, and subsequently the soldering gap between the carrier tube and the target segments is filled with solder coordinated to the materials. For this purpose, depending on the materials, both rising and falling fill techniques are to be selected, as well as the filling under pressure. For certain material combinations the filling with solder is advantageously performed under mechanical activation. After a complete filling with solder a defined cooling program is run for solidifying the solder.

In case of less stringent requirements for the heat conductivity of the tubular target as well as the strength of the tubular target, the segments are fixed on the carrier tube by an adhesive process. A heat-conducting adhesive serves for this purpose, filling the gap between the carrier tube and the target segments in a material-fitting manner. In case of low requirements for heat conductivity of the tubular targets and low sputtering power, the tubular segments can, under some circumstances, be fastened on the carrier tube even by spring-like systems or by clamping systems.

### BRIEF DESCRIPTION OF THE SEVERAL VIEWS OF THE DRAWINGS

The foregoing summary, as well as the following detailed description of the invention, will be better understood when read in conjunction with the appended drawings. For the purpose of illustrating the invention, there are shown in the drawings embodiments which are presently preferred. It should be understood, however, that the invention is not limited to the precise arrangements and instrumentalities shown. In the drawings:

FIG. 1 is schematic, longitudinal view of a tubular target according to an embodiment of the invention.

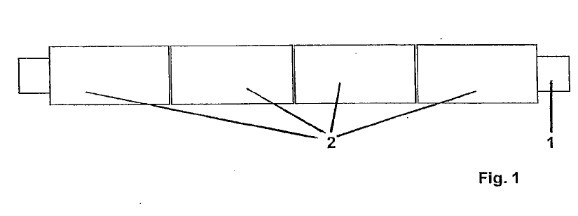

### DETAILED DESCRIPTION OF THE INVENTION

On a carrier tube 1 several tubular targets 2 are mounted in segments. In the following, the production is explained.

### EXAMPLE 1

A steel carrier tube 1 having a length of 1.5 m with an outer diameter 527 ₐ=133 mm, inner diameter Øᵢ=125 mm, is etched in a mixture of HCl:HNO₃ for preparation. Furthermore, the surface of the carrier tube 1 is roughened and activated via a brushing process. Subsequently, a Cu-layer is applied galvanically to the surface of the carrier tube as an intermediate layer having a thickness of approximately 0.02 mm. Three aluminum tubular segments 2 are produced by a centrifugal casting method, cut to a length of 0.4 m, and machined inside and outside to Øᵢ=135 mm, Øₐ=154 mm. The interior surface of the Al-segments is likewise galvanically copper-plated.

The intermediate layer of the carrier tube is covered overall with a Sn-solder foil approximately 0.5 mm thick, which is soldered by localized heating with a gas burner. The intermediate layer of the aluminum target tube segments 2 is covered overall by an indium foil, 0.5 nun thick, which is soldered by localized heating with a gas burner. Then, a thin lubricating film layer of an easily evaporable oil is applied to the two most recently applied layers. Next, the tube-shaped target segments 2 are pushed onto the carrier tube 1 via centering and distancing devices. The lubricant layer is rinsed off.

For homogeneous heating to soldering temperature, the prepared tubular target is homogeneously heated in a tube furnace to 200° C. Here, the last remnants of the lubricant layer are simultaneously heated off. In order to avoid oxidation/tarnishing effects, rinsing with protective gas occurs during the heating. After reaching the soldering temperature the tubular target is removed from the tube furnace, stood upright, and mounted in a vertical soldering device. Here, all gaps are sealed with rapid sealing clamps. During this preparation the tubular target is covered with thermally insulating material and held at 170° C. by an internal heating. Additionally, the inert gas rinsing is maintained.

Approximately 1.5 kg indium is melted as the solder, brought to 250° C., and filled into the soldering gap. In order to achieve a 100% filling of the soldering gap, a mechanical stimulation is coupled to the vertically positioned tubular target while the solder is being poured. As soon as the solder is filled in completely, all heating and insulating measures at the tube are withdrawn, and the cooling process is initiated via four multi-holed lances in the vertical soldering device using pressurized air. The cooling rate is controlled by gas valves. After cooling the tubular target to room temperature the tubular target can be disassembled from the vertical soldering device and solder remnants be cleaned off.

### EXAMPLE 2

A steel carrier tube 1 having a length of 1.5 m with an outer diameter Øₐ=133 mm, inner diameter Øᵢ=125 mm, is etched in a mixture of HCl:HNO₃ for preparation. Furthermore the surface of the carrier tube 1 is roughened in a sand-blasting process and activated. Then, a Ni-layer is applied using thermal spray technology to the surface of the carrier tube 1 as an intermediate layer having a thickness of approximately 0.2 mm. A Mo-tube having a length of 1.4 m with Øᵢ=135 mm, Øₐ=154, is produced by a powder-metallurgy process. The interior surface of the Mo-tube is brushed free from remnant scales and nickel-plated electrolessly. No additional layers are applied. The further operations of the soldering process correspond to Example 1.

### EXAMPLE 3

A steel carrier tube 1 having a length of 1.5 m with an outer diameter Øₐ=133 mm, inner diameter Øᵢ=125, is roughened in a brushing process for preparation and then coated with a galvanic Cu-layer. Two Cr-tube segments having a length of 0.7 m, with Øᵢ=135 mm, Øₐ=154 mm, are produced by a powder-metallurgy process. After being heated to 80° C. for liquefying the adhesive, both Cr-segments are adhered to the carrier tube 1 by a heat-conducting and electrically-conducting adhesive. In order to achieve a high degree of wetting between the adhesive and the target tube 2 and carrier tube 1, the target prepared as described above is held at approximately 80° C. for approximately 1 hour.

### EXAMPLE 4

A steel carrier tube 1 having a length of 1.5 m with an outer diameter Øₐ=133 mm, inner diameter Øᵢ=125 mm, is etched in a mixture of HCl:HNO₃ for preparation. The target material to be fastened comprises an Al-tube having a length of 1.4 m with Øᵢ=135 mm, Øₐ=155 mm. The interior surface is cleaned by a suitable surface treatment and roughened. No additional layers are applied. The further operations of the soldering process correspond to Example 1.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

1-13. (canceled)

14. A tubular target comprising a cylindrical carrier tube, at least one target tube arranged on an exterior surface of the carrier tube, and a connecting layer arranged between the target tube and the carrier tube, wherein the connecting layer is electrically conductive and has a wetting degree of >90%.

15. The tubular target according to claim 14, wherein the wetting degree amounts to >95%.

16. The tubular target according to claim 14, wherein the wetting degree is present both on the exterior surface of the carrier tube and on an interior surface of the target tube.

17. The tubular target according to claim 14, wherein connector pieces, bearing receptors or flanges are arranged on at least one end face of the carrier tube and/or the target tube.

18. The tubular target according to claim 14, wherein at least one target tube has an enlarged diameter on at least one end.

19. The tubular target according to claim 14, wherein the target tube comprises at least one material selected from the group consisting of Cu, Al, Zr, Mo, W, Ti, Cr, Ni, Ta, Nb, Ag, Zn, Bi, Sn, Si, alloys based on at least one of these elements, and a ceramic material.

20. The tubular target according to claim 19, wherein the target tube comprises an alloy of Al with a rare-earth element.

21. The tubular target according to claim 20, wherein the rare-earth element is Nd.

22. The tubular target according to claim 14, wherein the at least one target tube is fabricated by a method selected from the group consisting of formation from a compact material block, direct molding of hollow cylinders, extrusion, impact extrusion, sintering, and hot-isostatic pressing.

23. The tubular target according to claim 14, wherein the connecting layer comprises a conducting adhesive or a solder material.

24. The tubular target according to claim 23, wherein the connecting layer comprises the solder material applied directly on the carrier tube and/or the target tube.

25. The tubular target according to claim 23, wherein the connecting layer comprises at least one layer of an adhesive agent or a wetting agent with the solder material arranged on the at least one layer, and the connecting layer being arranged on the carrier tube and/or the target tube.

26. The tubular target according to claim 23, wherein the solder material is selected from the group consisting of In, Sn, InSn, and SnBi.

27. The tubular target according to claim 23, wherein the solder material comprises a low-melting solder alloy having a liquidus temperature below 300° C.

28. The tubular target according to claim 27, wherein the carrier tube and/or the target tube is coated with a nickel-based adhesive layer.

29. The tubular target according to claim 28, wherein the nickel-based adhesive layer comprises a nickel-aluminum or a nickel-titanium alloy.

30. A method for a producing display coating, the method comprising sputtering a substrate for the coating using the tubular target according to claim 14.
